(19) United States
(12) Patent Application Publication
(10) Pub. No.: US 2010/0065313 A1
(43) Pub. Date: Mar. 18, 2010

(54) MULTI-LAYER WIRING BOARD

(76) Inventors: Kazumasa Takeuchi, Ibaraki (JP); Nozomu Takano, Ibaraki (JP); Masaki Yamaguchi, Ibaraki (JP); Makoto Yanagida, Ibaraki (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/916,090

(22) PCT Filed: May 26, 2006
(86) PCT No.: PCT/JP2006/310532

§ 371 Date: Dec. 4, 2009

(30) Foreign Application Priority Data
May 30, 2005 (JP) 2005-157614
May 25, 2006 (JP) 2006-145458

(51) Int. Cl. H05K 1/14

(52) U.S. Cl. 174/258; 174/259

(57) ABSTRACT

It is an object of the present invention to provide a multilayer circuit board that can be housed at high density in the enclosures of electronic devices. According to a preferred embodiment of the invention, a multilayer circuit board (12) has a structure wherein non-flexible printed circuit boards (6) are laminated via cover lays (10) onto both sides of a flexible printed circuit board (1). In the multilayer circuit board (12), the cover lays (10) protect the regions of the printed circuit board (1) where the printed circuit boards (6) are not situated, while also functioning as adhesive layers (11) for bonding with the printed circuit boards (6). In other words, the same layers are used as the cover lays (10) and adhesive layers (11) in the multilayer circuit board (12).

### TECHNICAL FIELD

The present invention relates to a multilayer circuit board.

### BACKGROUND ART

Laminated sheets for printed circuit boards are obtained by stacking a prescribed number of prepregs comprising a resin composition with an electrical insulating property as the matrix, and heating and pressing the stack to form an integrated unit. Also, metal-clad laminated sheets are used when forming printed circuits by a subtractive process in the fabrication of printed circuit boards. Such metal-clad laminated sheets are manufactured by stacking metal foil such as copper foil on the prepreg surface (one or both sides), and heating and pressing the stack.

Thermosetting resins such as phenol resins, epoxy resins, polyimide resins, bismaleimide-triazine resins and the like are widely used as resins with electrical insulating properties. Thermoplastic resins such as fluorine resins or polyphenylene ether resins are also sometimes used.

However, the advancing development of data terminal devices such as personal computers and cellular phones has led to reduced sizes and higher densities of the printed circuit boards mounted therein. The mounting forms range from pin insertion types to surface mounting types, and are gradually shifting toward area arrays such as BGA (ball grid arrays) that employ plastic substrates.

For a substrate on which a bare chip such as BGA is directly mounted, connection between the chip and substrate is usually accomplished by wire bonding which employs thermosonic bonding. Bare chip-mounted substrates are thus exposed to high temperatures of 150° C. and above, and the electrical insulating resins must therefore have a certain degree of heat resistance.

Such substrates are also required to have “repairability” so that the once mounted chips can be removed. This requires approximately the same amount of heat as for mounting of the chips, while the chip must be remounted later on the substrate and subjected to further heat treatment. Consequently, “repairable” substrates must exhibit thermal shock resistance against high temperature cycles. Conventional insulating resins have also sometimes exhibited peeling between the resins and fiber base materials.

For printed circuit boards there have been proposed prepregs comprising a fiber base material impregnated with a resin composition comprising polyamideimide as an essential component, in order to improve the intricate wiring formability in addition to thermal shock resistance, reflow resistance and crack resistance (for example, see Patent document 1). There have also been proposed heat resistant substrates comprising a fiber base material impregnated with a resin composition composed of a silicone-modified polyimide resin and a thermosetting resin (for example, see Patent document 2).

In addition, with the increasing miniaturization and high performance of electronic devices it has become necessary to house printed circuit boards with parts mounted in more limited spaces. Methods are known for forming structures comprising a plurality of printed circuit boards so that the printed circuit boards can be disposed at a higher high density. For example, there is known a method of disposing a plurality of printed circuit boards in a stack and connecting them together with a wire harness or flexible wiring board (for example, see Patent document 3). In some cases, rigid-flex substrates are used which are multilayer stacks comprising polyimide-based flexible substrates and conventional rigid boards (for example, see Patent document 4).
[Patent document 1] Japanese Unexamined Patent Publication No. 2003-55486
[Patent document 2] Japanese Unexamined Patent Publication HEI No. 8-193139.
[Patent document 3] Japanese Unexamined Patent Publication No. 2002-064271
[Patent document 4] Japanese Unexamined Patent Publication HEI No. 6-302962.

### DISCLOSURE OF THE INVENTION

### Problems to be Solved by the Invention

However, printed circuit boards obtained by connecting a plurality of printed circuit boards using wire harnesses or flexible wiring boards as described above, or rigid-flex substrates, require spaces for connection or adhesive layers for multilayering, and it has therefore been quite difficult to achieve high density beyond a certain point.

In light of these circumstances, it is an object of the present invention to provide a multilayer circuit board that can be housed at high density in the enclosures of electronic devices.

### Means for Solving the Problems

In order to achieve this object, the multilayer circuit board of the invention is provided with a first printed circuit board comprising a first conductor circuit and having a cover lay formed on its surface, and a second printed circuit board comprising a second conductor circuit, which is laminated on the first printed circuit board via an adhesive layer, characterized in that the cover lay is the same layer as the adhesive layer.

The multilayer circuit board of the invention has a multilayer structure wherein the first printed circuit board and second printed circuit board are laminated. In this type of structure, the cover lay protecting the first conductor circuit of the first printed circuit board also serves as the adhesive layer bonding the first printed circuit board and second printed circuit board, as mentioned above. Therefore, it is not necessary to form an another adhesive layer for bonding between the printed circuit boards during multilayering, and smaller thicknesses can be achieved compared to the prior art. The multilayer circuit board of the invention is, as a result, more suitable for high density housing.

Moreover, since the multilayer circuit board of the invention has the same layer for the cover lay and adhesive layer and it is therefore unnecessary to form these of different structural materials, the dimensional stability is more satisfactory. In addition, using the same layer for the cover lay and adhesive layer also allows for more freedom of design of the multilayer circuit board.

The multilayer circuit board of the invention is preferably one provided with a first printed circuit board comprising a first conductor circuit, a cover lay formed on the surface of the first printed circuit board to cover the first conductor circuit and a second printed circuit board comprising a second conductor circuit, laminated in a partially discontinuous manner on the first printed circuit board, and is characterized in that the second printed circuit board is laminated on the first printed circuit board by bonding with the cover lay.

Since the cover lay of the first printed circuit board also serves as the adhesive layer for bonding between the first printed circuit board and second printed circuit board in the multilayer circuit board having this construction, it is easier to achieve smaller thicknesses and higher density housing. In particular, if the multilayer circuit board is foldable at regions where the second printed circuit board is not laminated on the first printed circuit board (regions where the second printed circuit board is discontinuous), it is easy to achieve a structure in which sections where the second printed circuit board is laminated become doubled, thus allowing even higher density housing.

The multilayer circuit board of the invention described above is preferably obtained by laminating a B-stage resin film on the first printed circuit board, stacking the second printed circuit board over this resin film, and heating and pressing the stack to form a cover lay from the resin film. The cover lay of this type of multilayer circuit board provides satisfactory bonding between the first printed circuit board and second printed circuit board, thus allowing the cover lay and adhesive layer functions to be exhibited more satisfactorily.

The first printed circuit board in the multilayer circuit board of the invention is preferably a freely foldable printed circuit board. This type of multilayer circuit board has non-flexible (rigid) regions of the laminated second printed circuit board introduced onto a flexible substrate composed of the first printed circuit board. The multilayer circuit board is suitable for a structure wherein rigid regions are stacked by folding at the flexible regions. As a result, the multilayer circuit board permits even higher density housing to be achieved.

The cover lay in the multilayer circuit board of the invention preferably contains a thermosetting resin composition. A cover lay containing a thermosetting resin composition has an excellent property of protecting the first conductor circuit of the first printed circuit board, while also allowing satisfactory bonding between the first printed circuit board and second printed circuit board.

The thermosetting resin composition preferably contains, specifically, at least one resin from among glycidyl group-containing resins, amide group-containing resins and acrylic resins. The substrate containing the thermosetting resin composition is one with satisfactory heat resistance and a good electrical insulating property, as well as mechanical strength and pliability, and can improve the strength and flexibility of the printed circuit board.

Also, the first printed circuit board of the multilayer circuit board of the invention preferably has a structure wherein the first conductor circuit is formed on a substrate which contains a pliable thermosetting resin composition. The first printed circuit board having such a substrate will exhibit flexibility to allow bending while having sufficient strength to prevent breakage by bending.

The first printed circuit board more preferably has a structure with the first conductor circuit formed on a substrate which contains a fiber base material, where the fiber base material is a glass cloth with a thickness of no greater than 50 μm. This will tend to exhibit the aforementioned effect in a more satisfactory manner. This type of first printed circuit board is especially superior from the standpoint of flexibility and strength.

### EFFECT OF THE INVENTION

The multilayer circuit board according to the invention employs the cover lay of one printed circuit board as an adhesive layer as well, and therefore facilitates thickness reduction compared to multilayered printed circuit boards of the prior art, to allow higher density housing. Moreover, since the multilayer circuit board has the same layer for the cover lay and adhesive layer, it has excellent dimensional stability and permits greater freedom of design.

### BRIEF DESCRIPTION OF THE DRAWINGS

FIG. 1 is a cross-sectional view schematically showing production steps for a multilayer circuit board.

### EXPLANATION OF SYMBOLS

1: Printed circuit board, 2: conductor circuits, 3: substrate, 4: resin films, 5: conductor circuits, 6: printed circuit boards, 7: substrates, 8: discontinuous region, 9: releasable base material, 10: cover lays, 11: adhesive layers, 12: multilayer circuit board, 26: flexible region, 36: non-flexible regions.

### BEST MODE FOR CARRYING OUT THE INVENTION

Preferred embodiments of the invention will now be described in detail.

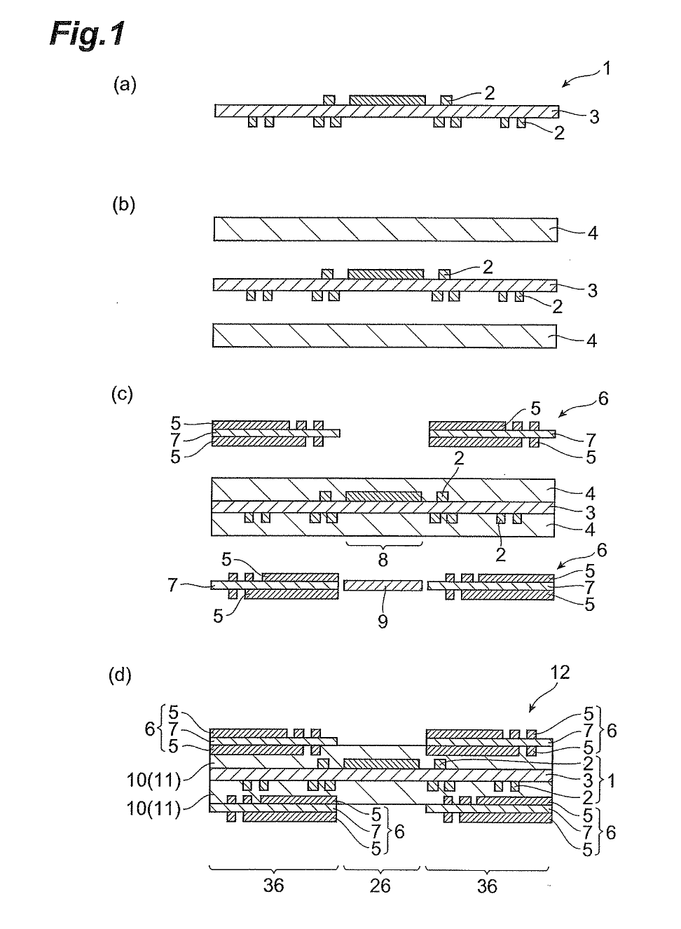

A preferred fabrication process for a multilayer circuit board of the invention will be explained first. The following explanation refers to FIG. 1 in describing a process for fabrication of a multilayer circuit board employing a circuit-containing polyimide substrate or epoxy substrate at the printed circuit board and using a B-stage resin film as the starting material for the cover lay.

FIG. 1 is a cross-sectional view schematically showing production steps for a multilayer circuit board.

Specifically, a printed circuit board 1 (first printed circuit board) comprising a freely foldable (flexible) substrate 3 and conductor circuits 2 (first conductor circuits) formed on both sides of the substrate 3 is prepared first, as shown in FIG. 1(a).

Next, as shown in FIG. 1(b), B-stage resin films 4 are situated on both sides of the printed circuit board 1, and the resin films 4 are laminated on the surfaces of the substrate 3 so as to cover the conductor circuits 2. The lamination is carried out in such a manner that the resin films 4 do not completely harden.

Separately, printed circuit boards 6 (second printed circuit boards) are prepared each having conductor circuits 5 (second conductor circuits) formed on both sides of a non-flexible (rigid) substrate 7. In each of the printed circuit boards 6, the region corresponding to the center section of the printed circuit board 1 is discontinuous. In other words, each printed circuit board 6 comprises a pair of printed circuit boards arranged in parallel with a spacing between them.

Next, as shown in FIG. 1(c), the printed circuit boards 6 are placed on both sides of the printed circuit board 1 on which the resin films 4 have been laminated. Although the two printed circuit boards 6 have different circuit patterns, the two printed circuit boards 6 are situated so that their discontinuous regions match. The discontinuous regions of the two printed circuit boards 6 are positioned so as to overlap the regions of the resin film 4—laminated printed circuit board 1 that require bending. This results in formation of regions without lamination of the printed circuit board 6, on both sides of the printed circuit board 1. As shown in the same drawing, a releasable base material 9 may also be situated in the discontinuous region 8 of the printed circuit board 6.

The structure laid in this manner is then subjected to heating and pressing in the direction of lamination. The heating and pressing may be carried out using a hot press, for example. This causes the B-stage resin films 4 to harden to the C-stage, resulting in formation of cover lays 10. After heating and pressing, the releasable base material 9 is peel off. Incidentally, through-holes may also be formed at prescribed locations of the resin films 4, and these may be filled with an electric conductor for interlayer connection between the conductor circuits 2 and 5.

This procedure yields a multilayer circuit board 12 having a structure with printed circuit boards 6 laminated on both sides of the printed circuit board 1 via cover lays 10, as shown in FIG. 1(d). The cover lays 10 in this multilayer circuit board 12 also function as adhesive layers 11 bonding the printed circuit board 1 and printed circuit board 6.

The construction of a multilayer circuit board according to a preferred embodiment will now be explained using as an example the multilayer circuit board 12 shown in FIG. 1(d), obtained by the preferred fabrication process described above.

As shown in the drawing, the multilayer circuit board 12 comprises monolayer regions composed only of the printed circuit board 1, and multilayer regions where the printed circuit board 1 and printed circuit boards 6 are laminated. In this multilayer circuit board 12, the printed circuit board 1 has satisfactory flexibility due to the freely foldable substrate 3, as mentioned above. The printed circuit boards 6, on the other hand, are non-flexible (rigid) due to the non-flexible substrates 7. Thus, the monolayer regions of the multilayer circuit board 12 form the flexible region 26 while the multilayer regions form the non-flexible regions 36.

Stated differently, the multilayer circuit board 12 comprises a flexible region 26 that can be folded and non-flexible regions 36 that cannot be folded, and it is constructed with a flexible printed circuit board 1 and printed circuit boards 6 laminated on the printed circuit board 1 in the non-flexible regions 36.

The term “flexible” refers to a property that allows at least 180° folding without significant breakage after folding. On the other hand, “non-flexible” means sufficient rigidity to prevent bending during ordinary expected use of the multilayer circuit board, although some bending that may occur with unexpected stress is included within the concept of “non-flexible”.

In a multilayer circuit board 12 having the construction described above, the substrate 3 used may be any one that is flexible and allows lamination of conductors, without any other restrictions. For example, a polyimide film or aramid film may be employed. From the viewpoint of flexibility and strength, the substrate 3 is preferably one containing a fiber base material.

Any fiber base material may be used which is commonly employed for fabrication of metal foil-clad laminates or multilayer printed circuit boards, with no particular restrictions, and as preferred examples there may be mentioned fiber base materials such as woven fabrics and nonwoven fabrics. The material of the fiber base material may be inorganic fiber such as glass, alumina, boron, silica-alumina glass, silica glass, tyranno, silicon carbide, silicon nitride, zirconia or the like, or organic fiber such as aramid, polyetheretherketone, polyetherimide, polyethersulfone, carbon, cellulose or the like, or a mixed fiber sheet of the above. Glass fiber woven fabrics are preferred.

When a prepreg is used as the material to form the substrate 3, the base material in the prepreg is most preferably a glass cloth with a thickness of no greater than 50 μm. Using a glass cloth with a thickness of no greater than 50 μm will facilitate fabrication of a printed circuit board that is flexible and freely foldable. It can also reduce dimensional changes that occur with temperature variation and moisture absorption during the fabrication process.

The substrate 3 is preferably one containing a fiber base material and a highly pliable insulating resin, and specifically it preferably has a construction with the fiber base material disposed in the insulating resin. Such a substrate 3 can be obtained by, for example, impregnating a fiber base material with an insulating resin before curing, and then curing the insulating resin. The starting material for the substrate 3 may be a prepreg comprising a fiber base material impregnated with the insulating resin in a semi-cured state.

The insulating resin preferably contains a thermosetting resin composition, and specifically it more preferably contains a cured thermosetting resin composition. The thermosetting resin in the thermosetting resin composition may be, for example, an epoxy resin, polyimide resin, unsaturated polyester resin, polyurethane resin, bismaleimide resin, triazine-bismaleimide resin, phenol resin or the like.

As mentioned above, the cover lays 10 are formed by curing the B-stage resin films 4. The resin films 4 preferably contain a thermosetting resin composition that is sufficiently pliable after curing. Such a thermosetting resin composition preferably contains an epoxy resin, polyimide resin, unsaturated polyester resin, polyurethane resin, bismaleimide resin, triazine-bismaleimide resin, phenol resin or the like.

Particularly when the substrate 3 contains an insulating resin with excellent pliability in the fiber base material as described above, it is highly preferred to use the same resin as the thermosetting resin composition in the insulating resin and the thermosetting resin composition of the resin films 4 forming the cover lays 10. A preferred thermosetting resin composition for the substrate 3 and resin films 4 will now be explained.

First, the thermosetting resin composition is one containing preferably a resin with glycidyl groups, more preferably a resin with glycidyl groups at the ends, and even more preferably a thermosetting resin such as an epoxy resin. As epoxy resins there may be mentioned polyglycidyl ethers obtained by reacting epichlorhydrin with a polyhydric phenol such as bisphenol A, a novolac-type phenol resin or an orthocresol-novolac type phenol resin or a polyhydric alcohol such as 1,4-butanediol, polyglycidyl esters obtained by reacting epichlorhydrin with a polybasic acid such as phthalic acid or hexahydrophthalic acid, N-glycidyl derivatives of compounds with amine, amide or heterocyclic nitrogen bases, and alicyclic epoxy resins.

If an epoxy resin is included as the thermosetting resin it is possible to carry out curing at a temperature of below 180° C. during molding of the substrate 3 and curing of the resin film 4, while better thermal, mechanical and electrical properties will tend to be exhibited.

A thermosetting resin composition containing an epoxy resin as the thermosetting resin also more preferably contains an epoxy resin curing agent or curing accelerator. For example, there may be used combinations of an epoxy resin with two or more glycidyl groups and a curing agent therefor, an epoxy resin with two or more glycidyl groups and a curing accelerator, or an epoxy resin with two or more glycidyl groups and a curing agent and curing accelerator. An epoxy resin with more glycidyl groups is preferred, and it even more preferably has three or more glycidyl groups. The preferred content of the epoxy resin will differ depending on the number of glycidyl groups, and the content may be lower with a larger number of glycidyl groups.

The epoxy resin curing agent and curing accelerator may be used without any particular restrictions so long as they react with the epoxy resin to cure it and accelerate curing. As examples there may be mentioned amines, imidazoles, polyfunctional phenols, acid anhydrides and the like. As amines there may be mentioned dicyandiamide, diaminodiphenylmethane and guanylurea. As polyfunctional phenols there may be used hydroquinone, resorcinol, bisphenol A and their halogenated forms, as well as novolac-type phenol resins and resol-type phenol resins that are condensates with formaldehyde. As acid anhydrides there may be used phthalic anhydride, benzophenonetetracarboxylic dianhydride, methylhymic acid and the like. As curing accelerators there may be used imidazoles including alkyl group-substituted imidazoles, benzimidazoles and the like.

Suitable contents for the curing agent or curing accelerator in the thermosetting resin composition are as follows. In the case of an amine, for example, it is preferably an amount such that the equivalents of active hydrogen in the amine are approximately equal to the epoxy equivalents of the epoxy resin. For an imidazole as the curing accelerator there is no simple equivalent ratio with active hydrogen, and its content is preferably about 0.001-10 parts by weight with respect to 100 parts by weight of the epoxy resin. For polyfunctional phenols or acid anhydrides, the amount is preferably 0.6-1.2 equivalents of phenolic hydroxyl or carboxyl groups per equivalent of the epoxy resin.

If the amount of curing agent or curing accelerator is less than the preferred amount, the uncured epoxy resin will remain after curing, and the Tg (glass transition temperature) of the cured thermosetting resin composition will be lower. If it is too great, on the other hand, unreacted curing agent or curing accelerator will remain after curing, potentially reducing the insulating property of the thermosetting resin composition.

A high-molecular-weight resin component may also be included as a thermosetting resin in the thermosetting resin composition for the substrate 3 or resin films 4, for improved pliability or heat resistance. As such thermosetting resins there may be mentioned amide group-containing resins and acrylic resins.

Polyamideimide resin is preferred as an amide group-containing resin, and siloxane-modified polyamideimide having a siloxane-containing structure is especially preferred. The siloxane-modified polyamideimide is most preferably one obtained by reaction of an aromatic diisocyanate with a mixture containing diimidedicarboxylic acid obtained by reaction of trimellitic anhydride and a mixture of a diamine with two or more aromatic rings (hereinafter, “aromatic diamine”) and a siloxanediamine.

The polyamideimide resin is preferably one containing at least 70 mol % of polyamideimide molecules having 10 or more amide groups in the molecule. The range for the content of the polyamideimide molecules can be obtained using a chromatogram from GPC of the polyamideimide and the separately determined number of moles of amide groups (A) per unit weight of the polyamideimide. Specifically, based on the number of moles of amide groups (A) in the polyamideimide (a) g, 10×a/A is first determined as the molecular weight (C) of the polyamideimide containing 10 amide groups per molecule. A resin wherein at least 70% of the regions have GPC chromatogram-derived number-average molecular weights of C or greater is judged as “containing at least 70 mol % of polyamideimide molecules having 10 or more amide groups in the molecule”. The method of quantifying the amide groups may be NMR, IR, a hydroxamic acid-iron color reaction or an N-bromoamide method.

A siloxane-modified polyamideimide having a siloxane-containing structure is preferably one wherein the mixing ratio of aromatic diamine (a) and siloxanediamine (b) is preferably a/b=99.9/0.1-0/100 (molar ratio), more preferably a/b=95/5-30/70 and even more preferably a/b=90/10-40/60. An excessively large mixing ratio for siloxanediamine (b) will tend to lower the Tg. If it is too small, however, the amount of varnish solvent remaining in the resin during fabrication of the prepreg will tend to increase.

As examples of aromatic diamines there may be mentioned 2,2-bis[4-(4-aminophenoxy)phenyl]propane, (BAPP), bis[4-(3-aminophenoxy)phenyl]sulfone, bis[4-(4-aminophenoxy)phenyl]sulfone, 2,2-bis[444-aminophenoxy)phenyl]hexafluoropropane, bis[4-(4-aminophenoxy)phenyl]methane, 4,4′-bis(4-aminophenoxy)biphenyl, bis[4-(4-aminophenoxy)phenyl]ether, bis[4-(4-aminophenoxy)phenyl]ketone, 1,3-bis(4-aminophenoxy)benzene, 1,4-bis(4-aminophenoxy)benzene, 2,2′-dimethylbiphenyl-4,4′-diamine, 2,2′-bis(trifluoromethyl)biphenyl-4,4′-diamine, 2,6,2′,6′-tetramethyl-4,4′-diamine, 5,5′-dimethyl-2,2′-sulfonyl-biphenyl-4,4′-diamine, 3,3′-dihydroxybiphenyl-4,4′-diamine, (4,4′-diamino)diphenyl ether, (4,4′-diamino)diphenylsulfone, (4,4′-diamino)benzophenone, (3,3′-diamino)benzophenone, (4,4′-diamino)diphenylmethane, (4,4′-diamino)diphenyl ether and (3,3′-diamino)diphenyl ether.

As siloxanediamines there may be mentioned those represented by the following general formulas (3)-(6). In the following formulas, n and m each represent an integer of 1-40.

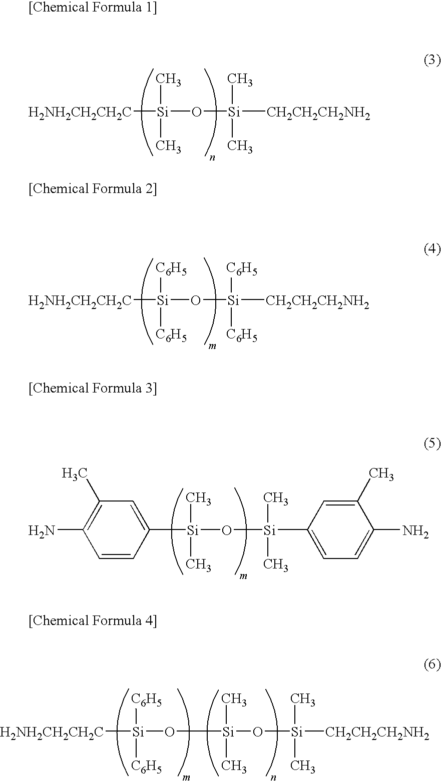

Examples of siloxanediamines represented by general formula (3) above include X-22-161AS (amine equivalents: 450), X-22-161A amine equivalents: 840) and X-22-161B (amine equivalents: 1500) (products of Shin-Etsu Chemical Co., Ltd.), and BY16-853 (amine equivalents: 650) and BY16-853B (amine equivalents: 2200) (products of Toray Dow Corning Silicone Co., Ltd.). Examples of siloxanediamines represented by general formula (6) above include X-22-9409 (amine equivalents: 700) and X-22-1660B-3 (amine equivalents: 2200) (products of Shin-Etsu Chemical Co., Ltd.).

For production of a siloxane-modified polyamideimide, a portion of the aromatic diamine may be replaced with an aliphatic diamine as the diamine component. As such aliphatic diamines there may be mentioned compounds represented by the following general formula (7).

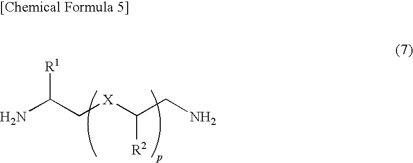

In this formula, X represents methylene, sulfonyl, ether, carbonyl or a single bond, R¹ and R² each independently represent hydrogen, alkyl, phenyl or a substituted phenyl group, and p is an integer of 1-50. Preferred for R¹ and R² are hydrogen, C1-3 alkyl, phenyl and substituted phenyl groups. As substituents that may be bonded to substituted phenyl groups there may be mentioned C₁₋₃ alkyl groups, halogen atoms and the like.

As aliphatic diamines there are particularly preferred compounds of general formula (7) above wherein X is an ether group, from the viewpoint of achieving both a low elastic modulus and a high Tg. Examples of such aliphatic diamines include JEFFAMINE D-400 (amine equivalents: 400) and JEFFAMINE D-2000 (amine equivalents: 1000).

The siloxane-modified polyamideimide can be obtained by reacting a diisocyanate with diimidedicarboxylic acid obtained by reacting a mixture containing the aforementioned siloxanediamine and aromatic diamine (preferably including an aliphatic diamine) with trimellitic anhydride. The diisocyanate used for the reaction may be a compound represented by the following general formula (8).

[Chemical Formula 6]

OCN-D-NCO (8)

In this formula, D is a divalent organic group with at least one aromatic ring or divalent aliphatic hydrocarbon group. For example, it is preferably at least one group selected from among groups represented by —C₆H₄—CH₂—C₆H₄—, tolylene, naphthylene, hexamethylene, 2,2,4-trimethylhexamethylene and isophorone.

As diisocyanates there may be mentioned both aromatic diisocyanates wherein D is an organic group with an aromatic ring, and aliphatic diisocyanates wherein D is an aliphatic hydrocarbon group. Aromatic diisocyanates are preferred diisocyanates, but preferably both of the above are used in combination.

As examples of aromatic diisocyanates there may be mentioned 4,4′-diphenylmethane diisocyanate (MDI), 2,4-tolylene diisocyanate, 2,6-tolylene diisocyanate, naphthalene-1,5-diisocyanate and 2,4-tolylene dimer. MDI is preferred among these. Using MDI as an aromatic diisocyanate can improve the flexibility of the obtained polyamideimide.

Examples of aliphatic diisocyanates include hexamethylene diisocyanate, 2,2,4-trimethylhexamethylene diisocyanate and isophorone diisocyanate.

When an aromatic diisocyanate and aliphatic diisocyanate are used in combination as mentioned above, the aliphatic diisocyanate is preferably added at about 5-10 mol % with respect to the aromatic diisocyanate. Using such a combination will tend to further improve the heat resistance of the polyamideimide.

An acrylic resin may also be used in addition to the glycidyl group-containing resin and the amide group-containing resin, as a thermosetting resin in the thermosetting resin composition used for the substrate 3 or resin films 4. As acrylic resins there may be mentioned polymers of acrylic acid monomers, methacrylic acid monomers, acrylonitriles and glycidyl group-containing acrylic monomers, as well as copolymers obtained by copolymerization of these monomers. The molecular weight of the acrylic resin is not particularly restricted, but it is preferably 300,000-1,000,000 and more preferably 400,000-800,000 as the weight-average molecular weight based on standard polystyrene.

The thermosetting resin composition for the substrate 3 or resin films 4 may also contain a flame retardant in addition to the aforementioned resin components. Including a flame retardant can improve the flame retardance of the substrate 1. For example, a phosphorus-containing filler is preferred as an added flame retardant. As phosphorus-containing fillers there may be mentioned OP930 (product of Clariant Japan, phosphorus content: 23.5 wt %), HCA-HQ (product of Sanko Co., Ltd., phosphorus content: 9.6 wt %), and the melamine polyphosphates PMP-100 (phosphorus content: 13.8 wt %), PMP-200 (phosphorus content: 9.3 wt %) and PMP-300 (phosphorus content: 9.8 wt %) (all products of Nissan Chemical Industries, Ltd.).

In the multilayer circuit board 12, the conductor circuits 2 and 5 are formed, for example, by working a metal foil or the like into a prescribed pattern by a publicly known photolithography technique. The metal foil used to form the conductor circuits 2,5 is not particularly restricted so long as it is a metal foil with a thickness of about 5-200 μm that is normally used for metal-clad laminated sheets and the like. Copper foil or aluminum foil is commonly used, for example. In addition to such simple metal foils, there may be used composite foils with a three-layer structure having nickel, nickel-phosphorus, nickel-tin alloy, nickel-iron alloy, lead, lead-tin alloy or the like as the interlayer between a 0.5-15 μm copper layer and a 10-300 μm copper layer on either side, or composite foils with a two-layer structure comprising aluminum and copper foil.

As shown in the drawing, the multilayer circuit board 12 comprises a flexible region 26 composed only of the printed circuit board 1, and non-flexible regions 36 where the printed circuit boards 6 are laminated on both sides of the printed circuit board 1. A multilayer circuit board 12 having such a construction can be easily folded at the flexible region 26, while the non-flexible regions 36 exhibit excellent rigidity. Thus, this type of multilayer circuit board 12 can easily adopt a structure which is folded at the flexible region 26 to allow high density housing even in narrow spaces such as inside electronic devices.

The multilayer circuit board 12 also uses the same layers (cover lays 10) as the cover lays for protection of the surfaces in the flexible region 12 and the adhesive layers bonding the printed circuit board 1 and printed circuit boards 6. It is therefore easier to obtain a reduced thickness than when separate layers are used, so that higher density housing can be achieved.

Moreover, in the conventional structure wherein the cover lay and adhesive layer are made of separate materials, the layers tend to vary in their dimensional change due to temperature variation during and after fabrication, making it difficult to obtain satisfactory dimensional stability. However, the multilayer circuit board 12 which has the same material for the cover lay and adhesive layer also exhibits excellent dimensional stability.

Furthermore, since the cover lays 10 also function as adhesive layers during fabrication of the multilayer circuit board 12, the printed circuit boards 6 can be laminated at any location of the cover lays 10. The multilayer circuit board 12 therefore allows for a very high degree of design freedom.

The multilayer circuit board of the invention, incidentally, is not limited to the embodiment described above and may incorporate a variety of modifications. For example, the multilayer circuit board 12 according to the embodiment described above comprises one printed circuit board 6 (second printed circuit board) laminated on each side of the printed circuit board 1 (first printed circuit board), but instead, two or more printed circuit boards may be laminated at these multilayer regions (non-flexible regions). Also, the flexible printed circuit board 1 does not necessarily have to be a single layer and may instead have a multilayer structure so long as it is flexible. However, the printed circuit boards 6 must be formed on the multilayer circuit board 12 in such a manner that the printed circuit board 1 has definite regions where the cover lays formed on its surfaces are exposed.

In addition, the multilayer circuit board 12 of the embodiment described above has only one flexible region 26, but there is no limitation to this structure, and for example, a plurality of discontinuous regions may be formed in the printed circuit boards 6 to create a plurality of flexible regions 26.

### EXAMPLES

The present invention will now be explained in greater detail through the following examples, with the understanding that these examples are in no way limitative on the invention.

### Example 1

First, a 50 μm-thick imide-based prepreg (product of Hitachi Chemical Co., Ltd.) including a 0.019 mm-thick glass cloth (1027, product of Asahi Shwebel) was prepared. Next, 18 μm-thick copper foils (F2-WS-18, product of Furukawa Circuit Foil Co., Ltd.) were superposed on both sides of the prepreg with the bonding surfaces facing the prepreg. This was then pressed with pressing conditions of 230° C., 90 minutes, 4.0 MPa to form a double-sided copper clad laminate.

Both sides of the double-sided copper-clad laminate were laminated with MIT-225 (product of Nichigo-Morton Co., Ltd., 25 μm thickness) as an etching resist and worked into prescribed patterns by a conventional photolithography technique. The copper foil was then etched with a ferric chloride-based copper etching solution to form patterns. It was then rinsed and dried to produce a foldable printed circuit board (first printed circuit board) comprising a first conductor circuit.

Both sides of the printed circuit board were vacuum laminated with 50 μm-thick imide-based adhesive films (product of Hitachi Chemical Co., Ltd.) at 100° C.

Separately, prescribed circuit patterns were formed on both sides of an MCL-I-67-0.2t-18 copper-clad laminate (product of Hitachi Chemical Co., Ltd.) by an ordinary photolithography technique, and rigid wiring boards (second printed circuit boards) comprising second conductor circuits were prepared.

The rigid wiring boards were situated at a prescribed positioning on the imide-based adhesive films laminated on the printed circuit board. The stack was then heated for 1 hour at 230° C., 4 MPa with a vacuum press, for bonding of the rigid wiring boards to the imide-based adhesive films and curing of the cover lay portions. This produced a multilayer circuit board having cover lays on the flexible portions (regions without the rigid wiring boards), wherein the same layers as the cover lays also served as the adhesive layers for the rigid wiring boards.

### Example 2

First, a 50 μm-thick acrylic/epoxy-based prepreg (product of Hitachi Chemical Co., Ltd.) including a 0.019 mm-thick glass cloth (1027, product of Asahi Shwebel) was prepared. Next, 18 μm-thick copper foils (HLA-18, product of Nippon Denkai Co., Ltd.) were superposed on both sides of the prepreg with the bonding surfaces facing the prepreg. This was then pressed with pressing conditions of 230° C., 90 minutes, 4.0 MPa to form a double-sided copper clad laminate.

Both sides of the double-sided copper-clad laminate were laminated with MIT-225 (product of Nichigo-Morton Co., Ltd., 25 μm thickness) as an etching resist and worked into prescribed patterns by a conventional photolithography technique. The copper foil was then etched with a ferric chloride-based copper etching solution to form patterns. It was then rinsed and dried to produce a printed circuit board (first printed circuit board) comprising a foldable first conductor circuit.

Both sides of the printed circuit board were vacuum laminated with 50 μm-thick acrylic/epoxy-based adhesive films (product of Hitachi Chemical Co., Ltd.) at 80° C.

Separately, prescribed circuit patterns were formed on both sides of an MCL-E-67-0.2t-18 copper-clad laminates (product of Hitachi Chemical Co., Ltd.) by an ordinary photolithography technique, and rigid wiring boards (second printed circuit boards) comprising second conductor circuits were prepared.

The rigid wiring boards were situated at a prescribed positioning on the acrylic/epoxy-based adhesive films laminated on the printed circuit board. The stack was then heated for 1 hour at 180° C., 4 MPa with a vacuum press, for bonding of the rigid wiring boards to the acrylic/epoxy-based adhesive films and curing of the cover lay portions. This produced a multilayer circuit board having cover lays on the flexible portions (regions without the rigid wiring boards), wherein the same layers as the cover lays also served as the adhesive layers for the rigid wiring boards.

### Example 3

Both sides of a double-sided copper-clad polyimide film (product of Ube Industries, Ltd.) were laminated with MIT-215 (product of Nichigo-Morton Co., Ltd., 15 μm thickness) as an etching resist and worked into prescribed patterns by a conventional photolithography technique. The copper foil was then etched with a ferric chloride-based copper etching solution to form patterns. It was then rinsed and dried to produce a printed circuit board (first printed circuit board) comprising a foldable first conductor circuit.

Both sides of the printed circuit board were vacuum laminated with 35 μm-thick imide-based adhesive films (product of Hitachi Chemical Co., Ltd.) at 100° C.

Separately, prescribed circuit patterns were formed on both sides of MCL-I-67-0.2t-18 copper-clad laminates (product of Hitachi Chemical Co., Ltd.) by an ordinary photolithography technique, and rigid wiring boards (second printed circuit boards) comprising second conductor circuits were prepared.

The rigid wiring boards were situated at a prescribed positioning on the imide-based adhesive films laminated on the printed circuit board. The stack was then heated for 1 hour at 230° C., 4 MPa with a vacuum press, for bonding of the rigid wiring boards to the imide-based adhesive films and curing of the cover lay portions. This produced a multilayer circuit board having cover lays on the flexible portions (regions without the rigid wiring boards), wherein the same layers also served as the adhesive layers for the rigid wiring boards.

(Folding Test)

When the multilayer circuit boards of Examples 1-3 were each folded at the flexible sections covered with the cover lays, all were freely foldable. Specifically, they could be folded 180° along a pin with a curvature radius of 0.5 mm.

1. A multilayer circuit board provided with
a first printed circuit board comprising a first conductor circuit and having cover lays formed on its surfaces, and
second printed circuit boards comprising second conductor circuits, which are laminated on the first printed circuit board via adhesive layers,
wherein the cover lays are the same layers as the adhesive layers.

2. A multilayer circuit board provided with
a first printed circuit board comprising first conductor circuits,
cover lays formed on the surfaces of the first printed circuit board covering the first conductor circuits and
second printed circuit boards comprising second conductor circuits, laminated in a partially discontinuous manner on the first printed circuit board,
wherein the second printed circuit boards are laminated on the first printed circuit board by bonding with the cover lays.

3. A multilayer circuit board according to claim 1, which is obtained by laminating B-stage resin films on the first printed circuit board, stacking the second printed circuit boards over the resin films, and heating and pressing the stack to form cover lays from the resin film.

4. A multilayer circuit board according to claim 1, wherein the first printed circuit board is a freely foldable printed circuit board.

5. A multilayer circuit board according to claim 1, wherein the cover lays comprise a thermosetting resin composition.

6. A multilayer circuit board according to claim 5, wherein the thermosetting resin composition comprises a glycidyl group-containing resin.

7. A multilayer circuit board according to claim 5, wherein the thermosetting resin composition comprises an amide group-containing resin.

8. A multilayer circuit board according to claim 5, wherein the thermosetting resin composition comprises an acrylic resin.

9. A multilayer circuit board according to claim 1, wherein the first printed circuit board has a structure with the first conductor circuits formed on a substrate, the substrate containing a fiber base material where the fiber base material is a glass cloth with a thickness of no greater than 50 μm.

10. A multilayer circuit board according to claim 2, which is obtained by laminating B-stage resin films on the first printed circuit board, stacking the second printed circuit boards over the resin films, and heating and pressing the stack to form cover lays from the resin film.

11. A multilayer circuit board according to claim 2, wherein the first printed circuit board is a freely foldable printed circuit board.

12. A multilayer circuit board according to claim 2, wherein the cover lays comprise a thermosetting resin composition.

13. A multilayer circuit board according to claim 12, wherein the thermosetting resin composition comprises a glycidyl group-containing resin.

14. A multilayer circuit board according to claim 12, wherein the thermosetting resin composition comprises an amide group-containing resin.

15. A multilayer circuit board according to claim 12, wherein the thermosetting resin composition comprises an acrylic resin.

16. A multilayer circuit board according to claim 2, wherein the first printed circuit board has a structure with the first conductor circuits formed on a substrate, the substrate containing a fiber base material where the fiber base material is a glass cloth with a thickness of no greater than 50 μm.
